(19) United States
(12) Patent Application Publication
(10) Pub. No.: US 2025/0259922 A1
(43) Pub. Date: Aug. 14, 2025

(54) SEMICONDUCTOR DEVICE

(71) Applicant: Rohm Co., Ltd., Kyoto-shi (JP)

(72) Inventor: Hiroaki AOYAMA, Kyoto-shi (JP)

(21) Appl. No.: 19/048,244

(22) Filed: Feb. 7, 2025

(30) Foreign Application Priority Data
Feb. 13, 2024 (JP) 2024-019376

(51) Int. Cl. H01L 23/498; H01L 23/00; H01L 23/13; H01L 23/31; H10D 80/20

(52) U.S. Cl. CPC H01L 23/49844; H01L 23/13; H01L 24/16; H01L 23/3121; H01L 23/49866; H01L 2224/16225; H01L 2924/1815; H10D 80/251

(57) ABSTRACT

A semiconductor device comprises a support, a first conductive portion, a semiconductor element disposed on one side of the thickness direction of the support and supported by the support. The semiconductor element includes a circuit portion, an element first face facing another side of the thickness direction, and a first electrode provided on the element first face. The support includes a first terminal portion and a second terminal portion. The first electrode is electrically connected to the circuit portion. The first terminal portion is electrically connected to the circuit portion via the first electrode. The first conductive portion is interposed between the second terminal portion and the element first face and is connected to the second terminal portion and the element first face. The first conductive portion includes a cross-sectional area that is smaller than a cross-sectional area of the first electrode orthogonal to the thickness direction.

### TECHNICAL FIELD

This disclosure relates to a semiconductor device.

### BACKGROUND ART

Various configurations of semiconductor devices with semiconductor elements have been proposed. JP-A-2020-77694 discloses an example of a conventional semiconductor device. The semiconductor device disclosed in JP-A-2020-77694 includes a lead and a semiconductor element. The lead includes a plurality of terminal portions. In the semiconductor device disclosed in JP-A-2020-77694, the semiconductor element is mounted on the lead by flip-chip mounting. The lead includes an obverse face facing one side in a thickness direction. The semiconductor element includes a plurality of electrodes provided on a side face facing the obverse face, and the plurality of electrodes are bonded to the obverse face of the lead via a bonding layer comprising, for example, solder. Each of the plurality of terminal portions is electrically connected to an internal circuit of the semiconductor element via at least one of the plurality of electrodes.

However, in the configuration in which the semiconductor element is mounted by flip-chip mounting as described above, even if damages such as cracks occur in a bonding portion between each of the plurality of electrodes and the lead, it is hard to determine whether or not the damages exist. Therefore, it is difficult to detect the damages of the bonding portion between the semiconductor element and the lead.

### BRIEF DESCRIPTION OF THE DRAWINGS

FIG. 1 is a plan view of a semiconductor device according to a first embodiment of the present disclosure (the sealing resin is omitted).

FIG. 2 is a plan view of the semiconductor device according to the first embodiment of the present disclosure (the semiconductor element and the sealing resin are omitted).

FIG. 3 is a bottom view of the semiconductor device according to the first embodiment of the present disclosure.

FIG. 4 is a cross-sectional view taken along a line IV-IV in FIG. 2.

FIG. 5 is a cross-sectional view taken along a line V-V in FIG. 2.

FIG. 6 is a cross-sectional view taken along a line VI-VI in FIG. 2.

FIG. 7 is a cross-sectional view taken along a line VII-VII in FIG. 2.

FIG. 8 is a partially enlarged view of FIG. 4.

FIG. 9 is a partially enlarged view of FIG. 4.

FIG. 10 is a partially enlarged view of FIG. 5.

FIG. 11 is a partially enlarged view of FIG. 6.

FIG. 12 is a plan view similar to FIG. 2, showing a semiconductor device according to the first variation of the first embodiment.

FIG. 13 is a plan view similar to FIG. 2, showing a semiconductor device according to the second variation of the first embodiment.

FIG. 14 shows a plan view similar to FIG. 2, showing a semiconductor device according to a third variation of the first embodiment.

FIG. 15 is a plan view similar to FIG. 2, showing a semiconductor device according to a fourth variation of the first embodiment.

### DETAILED DESCRIPTION OF EMBODIMENTS

The following describes preferred embodiments of the present disclosure in detail with reference to the drawings.

In the present disclosure, the terms such as “first”, “second”, and “third” are used merely as labels and are not intended to impose ordinal requirements on the items to which these terms refer.

In the description of the present disclosure, the expression “An object A is formed in an object B”, and “An object A is formed on an object B” imply the situation where, unless otherwise specifically noted, “the object A is formed directly in or on the object B”, and “the object A is formed in or on the object B, with something else interposed between the object A and the object B”. Likewise, the expression “An object A is disposed in an object B”, and “An object A is disposed on an object B” imply the situation where, unless otherwise specifically noted, “the object A is disposed directly in or on the object B”, and “the object A is disposed in or on the object B, with something else interposed between the object A and the object B”. Further, the expression “An object A is located on an object B” implies the situation where, unless otherwise specifically noted, “the object A is located on the object B, in contact with the object B”, and “the object A is located on the object B, with something else interposed between the object A and the object B”. Still further, the expression “An object A overlaps with an object B as viewed in a certain direction” implies the situation where, unless otherwise specifically noted, “the object A overlaps with the entirety of the object B”, and “the object A overlaps with a part of the object B”. Also, the phrase “an object A (or the material thereof) contains a material C” includes “an object A (or the material thereof) is made of a material C” and “an object A (or the material thereof) is mainly composed of a material C”. Furthermore, in the description of the present disclosure, the expression “A surface A faces (a first side or a second side) in a direction B” is not limited to the situation where the angle of the surface A to the direction B is 90° and includes the situation where the surface A is inclined with respect to the direction B.

### First Embodiment

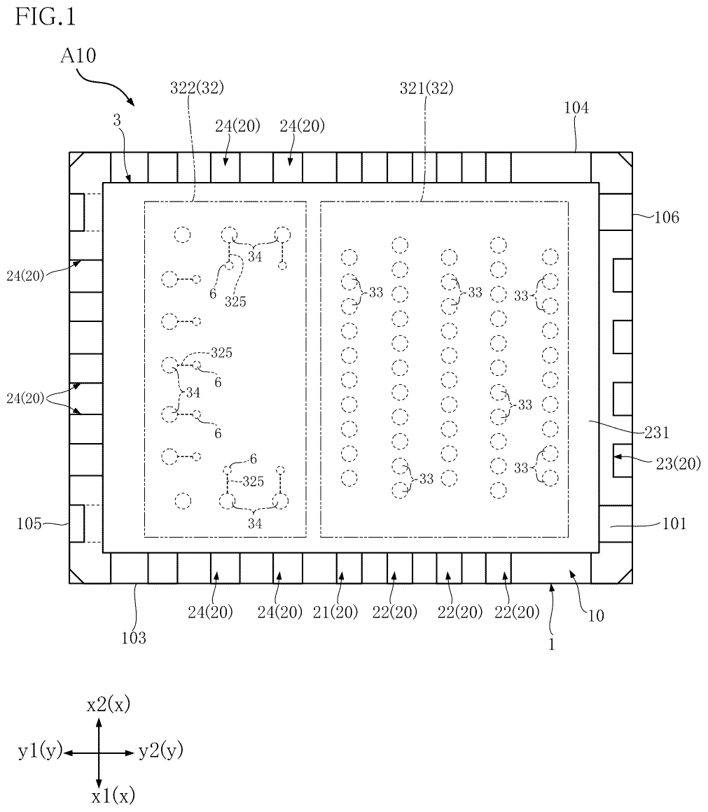

The semiconductor device of a first embodiment of the present disclosure will be described based on FIGS. 1 to 11. The semiconductor device A10 of the present embodiment includes a support 1, a semiconductor element 3, a sealing resin 4, and a plurality of first conductive portions 6. The sealing resin 4 is rectangular in plan view. The sealing resin 4 overlaps with the support 1 in plan view. The specific configuration of the semiconductor element 3 is not particularly limited, and the semiconductor element 3 is, for example, a flip-chip type LSI (Large Scale Integration). In the present embodiment, the semiconductor element 3 is, for example, a flip-chip LSI with a switching circuit 321 and a controlling circuit 322 (details of each are described below) configured therein. In the semiconductor device A10, DC power (voltage) is converted into AC power (voltage) by the switching circuit 321. The semiconductor device A10 is used, for example, as an element constituting a circuit of a DC/DC converter.

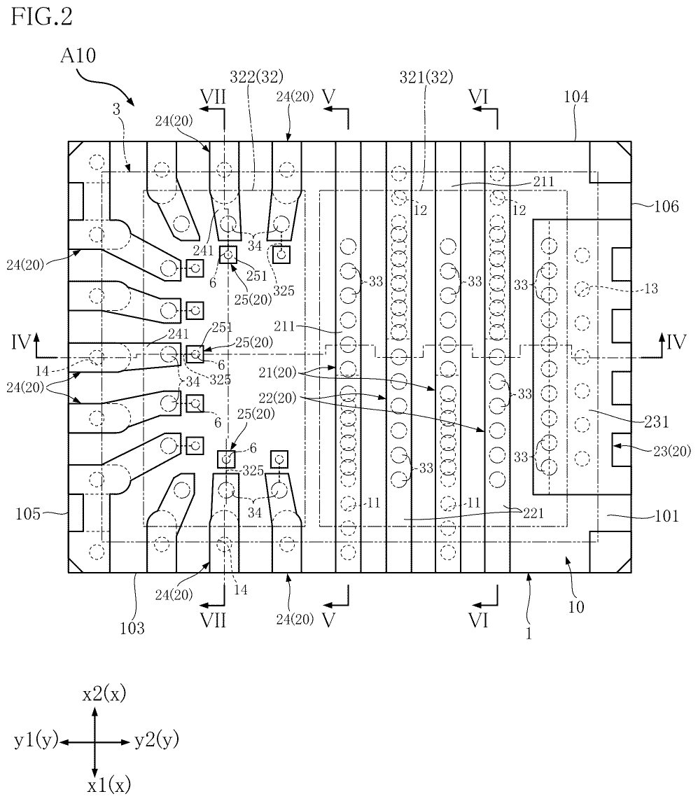

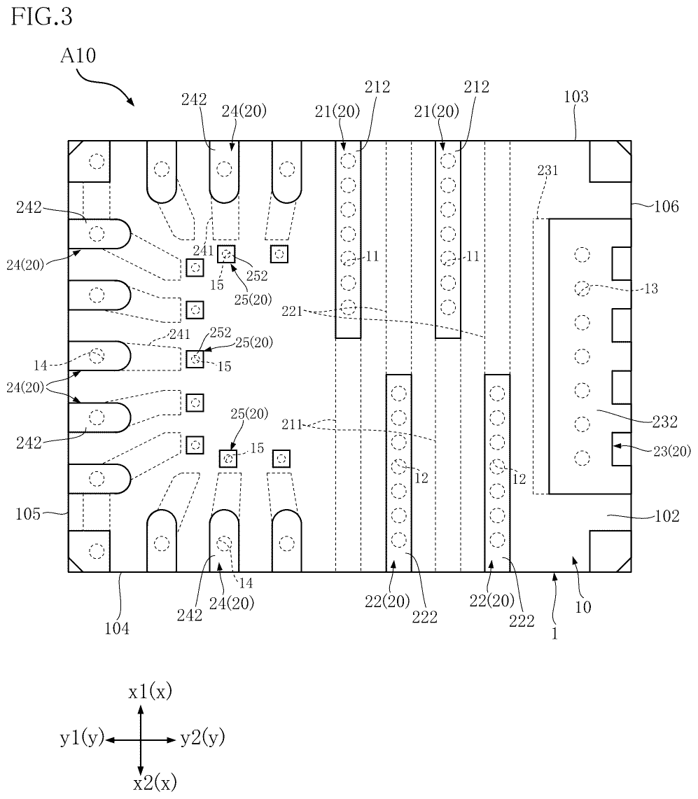

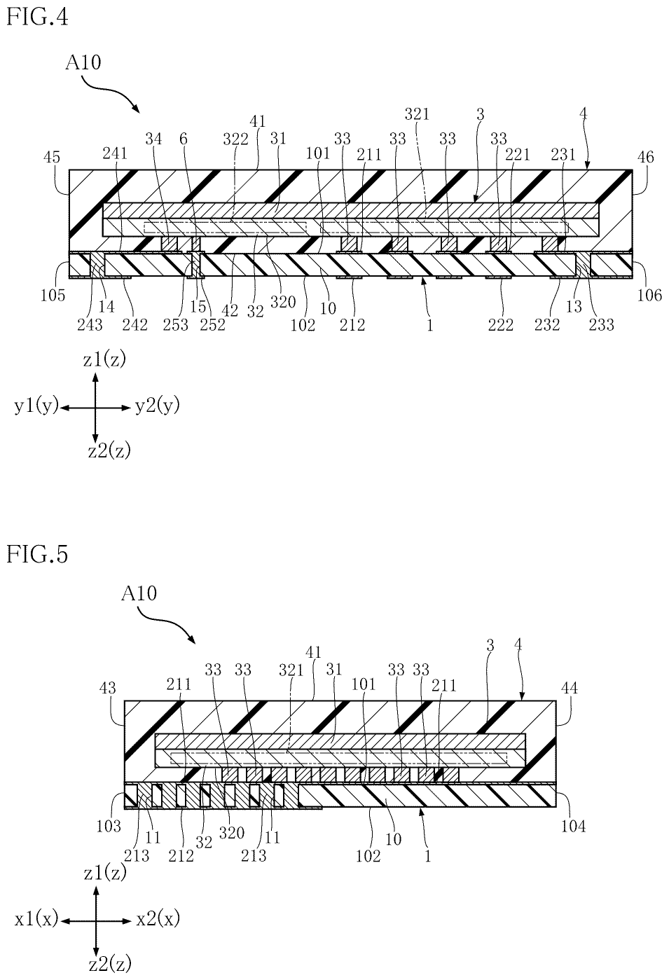

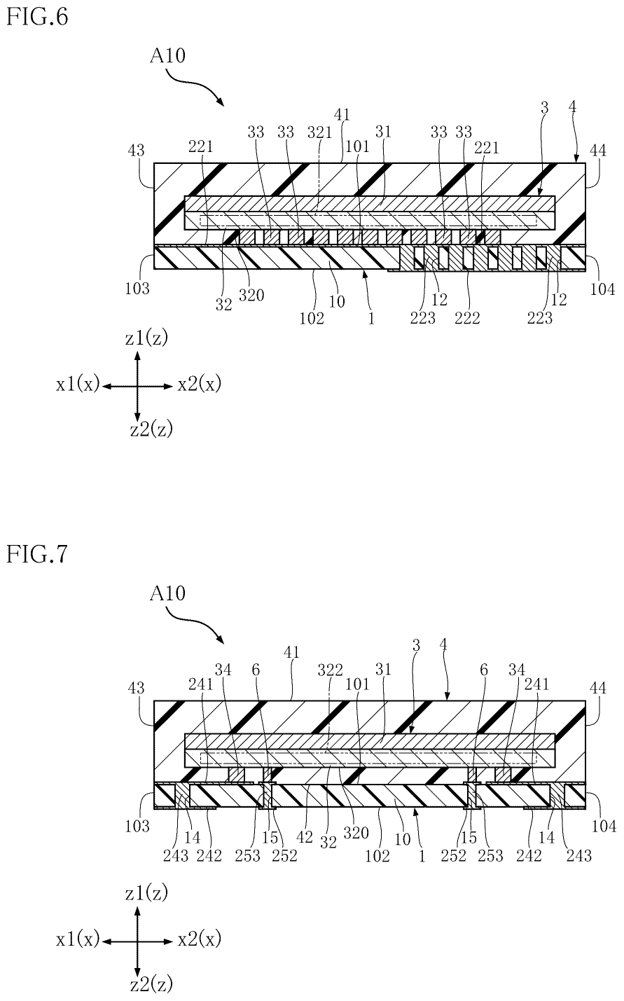

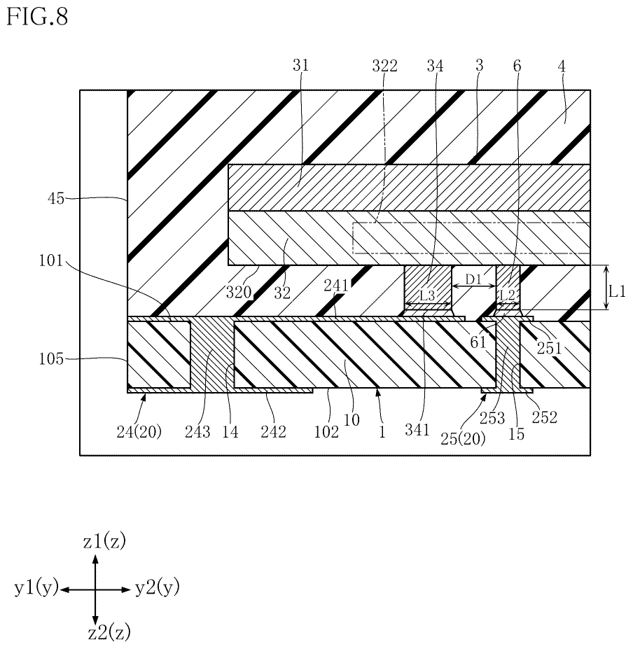

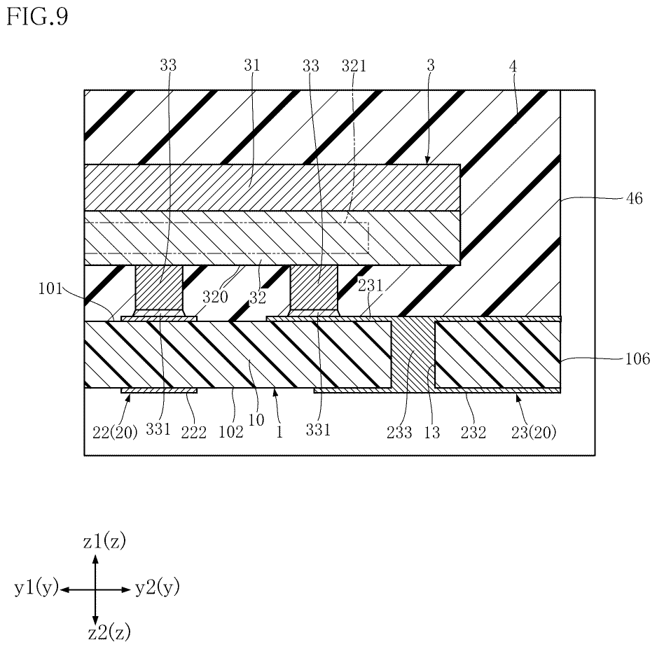

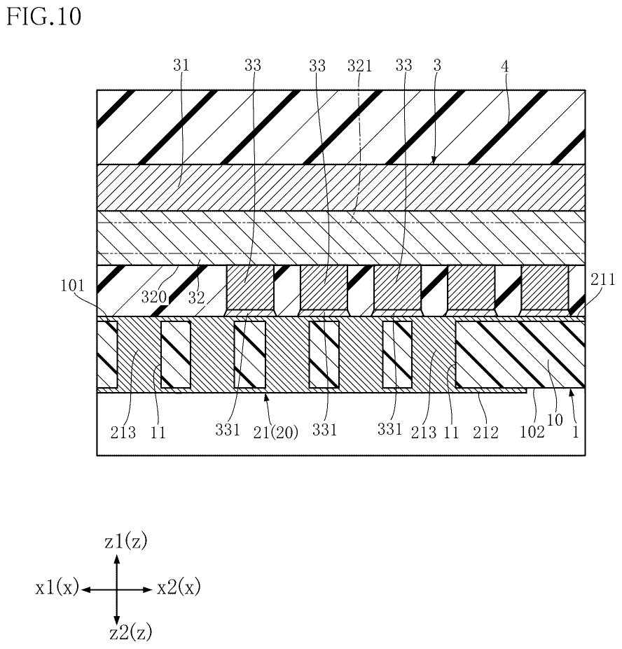

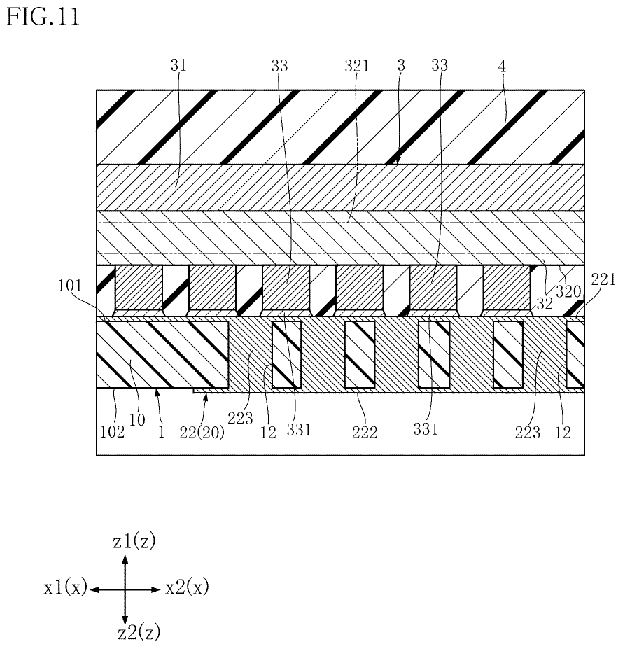

FIG. 1 is a plan view showing the semiconductor device A10. FIG. 2 is a plan view showing the semiconductor device A10. FIG. 3 is a bottom view showing the semiconductor device A10. FIG. 4 is a cross-sectional view taken along a line IV-IV line in FIG. 2. FIG. 5 is a cross-sectional view taken along a line V-V line in FIG. 2. FIG. 6 is a cross-sectional view taken along a line VI-VI line in FIG. 2. FIG. 7 is a cross-sectional view taken along a line VII-VII line in FIG. 2. FIGS. 8 and 9 are partially enlarged views of FIG. 4. FIG. 10 is a partially enlarged view of FIG. 5. FIG. 11 is a partially enlarged view of FIG. 6. The sealing resin 4 is omitted in FIG. 1 for the convenience of explanation. The semiconductor element 3 and the sealing resin 4 are omitted in FIG. 2 for the convenience of explanation. In FIG. 2, the omitted semiconductor element 3 is indicated as an imaginary line (double-dashed line).

In the explanation of the semiconductor device A10, the thickness direction (the plan-view direction) of the support 1 is an example of a “thickness direction” of the present disclosure and is referred to as a “thickness direction z”. A direction orthogonal to the thickness direction z (the horizontal direction shown in FIGS. 1 and 2) is referred to as a “first direction x”. A direction orthogonal to the thickness direction z and the first direction x (the vertical direction shown in FIGS. 1 and 2) is referred to as a “second direction y”. As shown in FIGS. 1 to 3, the semiconductor device A10 is a long rectangular shape as viewed in the thickness direction z. In the explanation of the semiconductor device A10, the lower side in FIG. 1 is referred to as an “x1 side of the first direction x”, and the upper side in FIG. 1 is referred to as an “x2 side of the first direction x” for the convenience of explanation. The left side in FIG. 1 is referred to as an “y1 side of the second direction y”, and the right side in FIG. 1 is referred to as an “y2 side of the second direction y”. In FIGS. 4 to 7, the upper side is an example of a “one side of the thickness direction” of the present disclosure and is referred to as a “z1 side of the thickness direction z”, and the lower side is an example of “another side of the thickness direction” of the present disclosure and is referred to as a “z2 side of the thickness direction z”.

The support 1 supports the semiconductor element 3, as shown in FIGS. 2 and 4 to 8. A part of the support 1 is covered by the sealing resin 4. In the present embodiment, the support 1 includes a substrate 10 and a wiring portion 20. The substrate 10 is made of an insulating material. The constituent material of the support 1 is not limited, and includes epoxy resin, glass epoxy resin, or ceramics, for example. The substrate 10 includes a substrate obverse face 101, a substrate reverse face 102, a substrate first side face 103, a substrate second side face 104, a substrate third side face 105, and a substrate fourth side face 106. The substrate obverse face 101 faces the z1 side of the thickness direction z and faces the semiconductor element 3. The substrate reverse face 102 faces the opposite side of the substrate obverse face 101 (another side of the thickness direction z). The substrate obverse face 101 is covered by the sealing resin 4. The substrate reverse face 102 is exposed from the sealing resin 4.

The substrate first side face 103 is located at the edge of the substrate 10 in the x1 side of the first direction x, and faces the x1 side of the first direction x. The substrate first side face 103 is connected to the substrate obverse face 101 and the substrate reverse face 102. The substrate second side face 104 is located at the edge of the substrate 10 in the x2 side of the first direction x, and faces the x2 side of the first direction x. The substrate second side face 104 is connected to the substrate obverse face 101 and the substrate reverse face 102. The substrate third side face 105 is located the edge of the substrate 10 in the y1 side of the second direction y, and faces the y1 side of the second direction y. The substrate third side face 105 is connected to the substrate obverse face 101 and the substrate reverse face 102. The substrate fourth side face 106 is located at the edge of the substrate 10 in the y2 side of the second direction y, and faces the y2 side of the second direction y. The substrate fourth side face 106 is connected to the substrate obverse face 101 and the substrate reverse face 102. The substrate 10 includes a plurality of through holes 11, a plurality of through holes 12, a plurality of through holes 13, a plurality of first through holes 14, and a plurality of second through holes 15. Each of the through holes 11-15 penetrates the substrate 10 in the thickness direction z.

The wiring portion 20 is disposed on the surface of the substrate 10, and constitutes a conduction pathway to the semiconductor element 3. The wiring portion 20 may be made of a metal such as copper (Cu), nickel (Ni), titanium (Ti), gold (Au), and the like. The wiring portion 20 includes a plurality of terminal portions 21, a plurality of terminal portions 22, a terminal portion 23, a plurality of first terminal portions 24, and a plurality of second terminal portions 25.

The plurality of terminal portions 21 are spaced apart from each other in the second direction y, as shown in FIG. 2. In the present embodiment, the wiring portion 20 includes two terminal portions 21. One of the terminal portions 21 is located near the center of the substrate 10 in the second direction y. The other terminal portion 21 is located offset to the y2 side of the second direction y in the substrate 10. Each terminal portion 21 extends in the first direction x. Each terminal portion 21 is provided to receive DC power (voltage) to be converted by the semiconductor device A10. The terminal portion 21 is a positive electrode (P terminal). The terminal portions 21 each include an obverse face portion 211, a reverse face portion 212 and connection portions 213, as shown in FIGS. 4, 5 and 10.

The obverse face portion 211 is disposed on the substrate obverse face 101. In the illustrated example, the obverse face portion 211 extends in the first direction x from the end of the x1 side to the end of the x2 side on the substrate obverse face 101. The reverse face portion 212 is disposed on the substrate reverse face 102. The reverse face portion 212 extends in the first direction x and overlaps with the obverse face portion 211 as viewed in the thickness direction z. The reverse face portion 212 extends in the first direction x from the end of the x1 side to the vicinity of the center on the substrate reverse face 102. The reverse face portion 212 is exposed from the sealing resin 4.

The connection portions 213 are disposed in the respective through holes 11 and are connected to the obverse face portion 211 and the reverse face portion 212. The substrate 10 is provided with the through holes 11 that overlap with the obverse face portion 211 and the reverse face portion 212 as viewed in the thickness direction z. The through holes 11 are arranged along the first direction x, and the connection portions 213 are disposed in the respective through holes 11. In the illustrated example, the connection portions 213 are provided by filling the respective through holes 11 with metal. Unlike the illustrated example, the connection portions 213 may be provided by forming plating layers composed of metal on the inner surface of the respective through holes 11. In this case, the interior of the connection portions 213 may be filled with resin.

The plurality of terminal portions 22 are spaced apart from each other in the second direction y. In the present embodiment, the wiring portion 20 includes two terminal portions 22. One of the terminal portions 22 is located between the two terminal portions 21 in the second direction y. The other terminal portion 22 is located on the y2 side of the second direction y than the terminal portion 21. Each terminal portion 22 extends in the first direction x. Each terminal portion 22 is provided to output AC power (voltage) converted by the switching circuit 321 in the semiconductor element 3. The terminal portions 22 each include an obverse face portion 221, a reverse face portion 222 and connection portions 223, as shown in FIGS. 4, 6 and 11.

The obverse face portion 221 is disposed on the substrate obverse face 101. In the illustrated example, the obverse face portion 221 extends in the first direction x from the end of the x1 side to the end of the x2 side on the substrate obverse face 101. The reverse face portion 222 is disposed on the substrate reverse face 102. The reverse face portion 222 extends in the first direction x and overlaps with the obverse face portion 221 as viewed in the thickness direction z. The reverse face portion 222 extends in the first direction x from the end of the x2 side to the vicinity of the center on the substrate reverse face 102. The reverse face portion 222 is exposed from the sealing resin 4.

The connection portions 223 are disposed in the respective through holes 12 and are connected to the obverse face portion 221 and the reverse face portion 222. The substrate 10 is provided with the through holes 12 that overlap with the obverse face portion 221 and the reverse face portion 222 as viewed in the thickness direction z. The through holes 12 are arranged along the first direction x, and the connection portions 223 are disposed in the respective through holes 12. In the illustrated example, the connection portions 223 are provided by filling the respective through holes 12 with metal. Unlike the illustrated example, the connection portions 223 may be provided by forming plating layers composed of metal on the inner surface of the respective through holes 12. In this case, the interior of the connection portions 223 may be filled with resin.

As shown in FIG. 2, the terminal portion 23 is located near the end of the substrate 10 in the y1 side (right side in FIG. 2) of the second direction y, and is disposed adjacent to one of the terminal portions 22 on the y2 side of the second direction y. One of the terminal portions 22 is located between the two terminal portions 21 in the second direction y. The other terminal portion 22 is located on the y2 side of the second direction y than the terminal portion 21. The terminal portion 23 extends in the first direction x. The terminal portion 23 is provided to receive DC power (voltage) to be converted by the semiconductor device A10. The terminal portion 23 is a negative electrode (N terminal). The terminal portion 23 includes an obverse face portion 231, a reverse face portion 232, and connection portions 233, as shown in FIGS. 4 and 9.

The obverse face portion 231 is located on the substrate obverse face 101. In the illustrated example, the obverse face portion 221 extends in the first direction x from near the end of the x1 side to near the end of the x2 side on the substrate obverse face 101. The reverse face portion 232 is disposed on the substrate reverse face 102. The reverse face portion 232 extends in the first direction x and overlaps with the obverse face portion 231 as viewed in the thickness direction z. The reverse face portion 232 extends from near the end of the x1 side to near the end of the x2 side on the substrate reverse face 102. The reverse face portion 232 is exposed from the sealing resin 4.

The connection portions 233 are disposed in the respective through holes 13 and are connected to the obverse face portion 231 and the reverse face portion 232. The substrate 10 is provided with the through holes 13 that overlap with the obverse face portion 231 and the reverse face portion 232 as viewed in the thickness direction z. The through holes 13 are arranged along the first direction x, and the connection portions 233 are disposed in the respective through holes 13. In the illustrated example, the connection portions 233 are provided by filling the respective through holes 13 with metal. Unlike the illustrated example, the connection portions 233 may be provided by forming plating layers composed of metal on the inner surface of the respective through holes 13. In this case, the interior of the connection portions 233 may be filled with resin.

As shown in FIG. 2, the plurality of first terminal portions 24 are located on the y1 side (left side in the figure) in the second direction y than the terminal portions 21. Several first terminal portions 24 are located on the x1 side (lower side in FIG. 2) of the first direction x in the substrate 10. Several first terminal portions 24 are located on the x2 side (upper side in FIG. 2) of the first direction X in the substrate 10. The remainder of the plurality of first terminal portions 24 are located on the y1 side (left side in FIG. 2) of the first direction x in the substrate 10. Each first terminal portion 24 is provided to receive, for example, power (voltage) to drive the controlling circuit 322 or electrical signals to be transmitted to the controlling circuit 322. Each first terminal portion 24 includes a first obverse face portion 241, a first reverse face portion 242 and a first connection portion 243, as shown in FIGS. 4, 7 and 8.

The first obverse face portion 241 is disposed on the substrate obverse face 101. The first reverse face portion 242 is disposed on the substrate reverse face 102. The first reverse face portion 242 overlaps with the first obverse face portion 241 as viewed in the thickness direction z. The first reverse face portion 242 is exposed from the sealing resin 4.

The first connection portion 243 is disposed in the first through hole 14, and is connected to the first obverse face portion 241 and the first reverse face portion 242. The substrate 10 is provided with the first through holes 14 that overlap with the respective first obverse face portions 241 and the respective first reverse face portions 242 as viewed in the thickness direction z, and the first connection portion 243 is disposed in the first through hole 14. In the illustrated example, the first connection portions 243 is provided by filling the first through hole 14 with metal. Unlike the illustrated example, the first connection portion 243 may be provided by forming a plating layer composed of metal on the inner surface of the through hole 14. In this case, the interior of the first connection portion 243 may be filled with resin.

As shown in FIG. 2, the plurality of second terminal portions 25 are adjacent to the respective first terminal portions 24. As understood from FIGS. 2, 4 and 7, the second terminal portions 25 are located inwardly of the sealing resin 4 than the respective first terminal portions 24 as viewed in the thickness direction z. Each second terminal portion 25 includes a second obverse face portion 251, a second reverse face portion 252 and a second connection portion 253, as shown in FIGS. 4, 7 and 8.

The second obverse face portion 251 is disposed on the substrate obverse face 101. The second obverse face portion 251 (second terminal portion 25) is connected to the first conductive portion 6. The second reverse face portion 252 is disposed on the substrate reverse face 102. The second reverse face portion 252 overlaps with the second obverse face portion 251 as viewed in the thickness direction z. The second reverse face portion 252 is exposed from the sealing resin 4.

The second connection portion 253 is disposed in the second through hole 15, and is connected to the second obverse face portion 251 and the second reverse face portion 252. The substrate 10 is provided with the second through holes 15 that overlap with the respective second obverse face portions 251 and the respective second reverse face portions 252 as viewed in the thickness direction z, and the second connection portion 253 is disposed in the second through hole 15. In the illustrated example, the second connection portion 253 is provided by filling the second through hole 15 with metal. Unlike the illustrated example, the second connection portion 253 may be provided by forming a plating layer composed of metal on the inner surface of the second through hole 15. In this case, the interior of the second connection portion 253 may be filled with resin.

The terminal portions 21, the terminal portions 22, the terminal portion 23, the first terminal portions 24, and the second terminal portions 25, may, for example, be tin-plated on their portions exposed from the sealing resin 4 (reverse face portions 212, 222, 232, first reverse face portion 242 and second reverse face portion 252). Instead of tin-plating, a metal plating may be applied in layers of nickel, palladium, and gold in this order, for example.

The semiconductor element 3 includes a semiconductor layer 32, a plurality of substrate 31, a semiconductor electrodes 33, and a plurality of first electrodes 34. As shown in FIGS. 4 to 7, the semiconductor layer 32, the semiconductor substrate 31 supports the electrodes 33 and the first electrodes 34 on its lower side. The constituent material of the semiconductor substrate 31 is, for example, Si (silicon) or silicon carbide (Sic).

The semiconductor layer 32 is stacked on the side of the semiconductor substrate 31 that opposes the substrate obverse face 101 in the thickness direction z. The semiconductor layer 32 includes an element first face 320. The element first face 320 faces the z2 side of the thickness direction z and the substrate obverse face 101 in the thickness direction z. The semiconductor layer 32 includes multiple types of p-type and n-type semiconductors based on differences in the amount doped elements. The of semiconductor layer 32 includes a switching circuit 321 and a controlling circuit 322 that is electrically connected to the switching circuit 321. The switching circuit 321 is a MOSFET (Metal-Oxide-Semiconductor Field-Effect Transistor), an IGBT (Insulated Gate Bipolar Transistor), or the like. In the example indicated by the semiconductor device A10, the switching circuit 321 is divided into two regions, namely a high-voltage region (upper arm circuit) and a low-voltage region (lower arm circuit). The regions are each composed of one n-channel MOSFET. The controlling circuit 322 includes a gate driver for driving the switching circuit 321, a bootstrap circuit corresponding to the high-voltage region of the switching circuit 321, and the like, and performs control for normally running the switching circuit 321. Further, a wiring layer (not shown) is included in the semiconductor layer 212. The switching circuit 321 and the control circuit 322 are electrically connected to each other via the wiring layer. The switching circuit 321 and the controlling circuit 322 are examples of a “circuit portion”.

As shown in FIGS. 4 to 7, the electrodes 33 and the first electrodes 34 are provided on the element first face 320 that opposes the substrate obverse face 101 in the thickness direction z. The electrodes 33 and the first electrodes 34 are in contact with the semiconductor layer 32.

The electrodes 33 are electrically connected to the switching circuit 321 of the semiconductor layer 32. Each of electrodes 33 is connected to one of the terminal portions 21 (obverse face portion 211), the terminal portions 22 (obverse face portion 221) and the terminal portions 23 (obverse face portion 231). The electrodes 33 are connected to the respective obverse face portions 211 (obverse face portions 221, 231) via a bonding layer with conductive properties, such as solder or the like (see bonding layer 331 in FIGS. 9 to 11). As a result, the terminal portions 21 (obverse face portions 211), the terminal portions 22 (obverse face portions 221) and the terminal portions 23 (obverse face portions 231) are each electrically connected to the switching circuit 321 via at least one of the electrodes 33.

The first electrodes 34 are electrically connected to the controlling circuit 322 of the semiconductor layer 32. Each of the first electrodes 34 is connected to the first obverse face portion 241 of one of the first terminal portions 24. The first electrodes 34 are, as with the electrodes 33, connected to the respective first obverse face portions 241 via a bonding layer with conductive properties, such as solder or the like (see bonding layer 341 in FIG. 8). As a result, each of the first terminal portions 24 (first obverse face portions 241) is electrically connected to the controlling circuit 322 via the first electrode 34. The constituent materials of the electrodes 33 and the first electrodes 34 include, for example, copper.

As shown in FIGS. 2, 4, 7 and 8, the first conductive portion 6 is interposed between the second obverse face portion 251 of the second terminal portion 25 and the element first face 320 of the semiconductor element 3. The first conductive portion 6 is connected to the second obverse face portion 251 (second terminal portion 25) and the element first face 320. As shown in FIG. 8, the first conductive portion 6 is connected to the upper surface of the second obverse face portion 251 (the surface facing the z1 side of the thickness direction z) via a bonding layer 61 with conductive properties such as solder. In the present embodiment, a plurality of first conductive portions 6 are provided to be interposed between the respective second terminal portions 25 (second obverse face portions 251) and the element first face 320 of the semiconductor layer 32, as shown in FIGS. 2, 4, 7, and 8. Each of the first conductive portions 6 overlaps with the second connection portion 253 as viewed in the thickness direction z.

As shown in FIGS. 2, 4, 7 and 8, each of the first conductive portions 6 is adjacent to one of first electrodes 34. As understood from FIGS. 2, 4 and 7, the first conductive portions 6 are located inwardly of the sealing resin 4 than the respective first electrodes 34 as viewed in the thickness direction z.

As shown in FIGS. 4, 7 and 8, a first cross-sectional area of the first conductive portion 6 in a plane orthogonal to the thickness direction z is smaller than a second cross-sectional area of the first electrode 34 in a plane orthogonal to the thickness direction. The ratio of the first cross-sectional area (cross-sectional area of the first conductive portion 6) to the second cross-sectional area (cross-sectional area of the first electrode 34) is between 30% and 95%, preferably between 30% and 50%. As shown in FIG. 8, a dimension L1 of the first conductive portion 6 in the thickness direction z is between 250% and 500%, preferably between 250% and 300% of a dimension L2 of the first conductive portion 6 in the direction orthogonal to the thickness direction z. A distance D1 between the first conductive portion 6 and the first electrode 34 is between 100% and 300%, preferably between 100% and 200% of a dimension L3 of the first electrode 34 in the direction orthogonal to the thickness direction z.

In the present embodiment, the semiconductor element 3 includes a first wiring 325 provided in the semiconductor layer 32 (see FIGS. 2 and 3). In FIGS. 2 and 3, the path of the first wiring 325 is indicated by a simplified dotted line. The first wiring 325 is electrically connected to each of the first conductive portions 6 and one of the first electrodes 34 adjacent to the respective first conductive portions 6. The first wiring 325 is an example of a “a connection check wiring”.

As shown in FIGS. 4 to 7, the sealing resin 4 includes a resin obverse face 41, a resin reverse face 42, a resin first side face 43, a resin second side face 44, a resin third side face 45, and a resin fourth side face 4. The constituent material of the sealing resin 4 is, for example, black epoxy resin.

As shown in FIGS. 4 to 7, the resin obverse face 41 faces the same side as the substrate obverse face 101 in the thickness direction z (z1 side of the thickness direction z). The resin reverse face 42 faces the opposite side of the resin obverse face 41 (z2 side of thickness direction z) and covers the substrate obverse face 101.

As shown in FIGS. 5 to 7, the resin first side face 43 is located at the edge of the sealing resin 4 in the x1 side of the first direction x, and faces the x1 side of the first direction x. The resin first side face 43 is connected to the resin obverse face 41 and the resin reverse face 42. The resin first side face 43 is flush with the substrate first side face 103 of the substrate 10.

As shown in FIGS. 5 to 7, the resin second side face 44 is located at the end of the sealing resin 4 in the x2 side of the first direction x, and faces the x2 side of the first direction x. The resin second side face 44 is connected to the resin obverse face 41 and the resin reverse face 42. The resin second side face 44 is flush with the substrate second side face 104 of the substrate 10.

As shown in FIG. 4, the resin third side face 45 is located at the end of the sealing resin 4 in the y1 side of the second direction y, and faces the y1 side of the second direction y. The resin third side face 45 is connected to the resin obverse face 41 and the resin reverse face 42. The resin third side face 45 is flush with the substrate third side face 105 of the substrate 10.

As shown in FIG. 4, the resin fourth side face 46 is located at the end of the sealing resin 4 in the y2 side of the second direction y and faces the y2 side of the second direction y. The resin fourth side face 46 is connected to the resin obverse face 41 and the resin reverse face 42. The resin fourth side face 46 is flush with the substrate fourth side face 106 of the substrate 10.

Next, the effects of the present embodiment will be described.

In the semiconductor device A10, the semiconductor element 3 includes the element first face 320 facing the z2 side of the thickness direction z and the plurality of first electrodes 34 provided on the element first face 320. The plurality of first electrodes 34 are connected to the first obverse face portion 241 (first terminal portion 24), and each of the first terminal portions 24 is electrically connected to the control circuit 322 (circuit portion) of the semiconductor element 3 via at least one of the plurality of first electrodes 34. The semiconductor device A10 further includes a first conductive portion 6 interposed between the first obverse face portion 241 (first terminal portion 24) and the element first face 320, and the first conductive portion 6 is connected to the first obverse face portion 241 (first terminal portion 24) of the support 1 and the element first face 320. The cross-sectional area (first cross-sectional area) of the first conductive portion 6 in a plane orthogonal to the thickness direction z is smaller than the cross-sectional area (second cross-sectional area) of the first electrode 34 in a plane orthogonal to the thickness direction z.

The semiconductor device A10 comprises the first conductive portion 6. The first conductive portion 6 has a smaller cross-sectional area than the first electrode 34, and is thinner than the first electrode 34. Such a configuration results in the bonding strength between the first conductive portion 6 and the support 1 being lower than the bonding strength between the first electrode 34 and the support 1. It is possible to check the state of the bonding portion of the first conductive portion 6 by electrically examining the relevant bonding of the first conductive portion 6. Since the bonding strength of the first conductive portion 6 is lower than the bonding strength of the first electrode 34 as described above, the fact that there is no abnormality in the bonding portion of the first conductive portion 6 determines that there is no abnormality in the bonding portion of the first electrode 34. Hence, the semiconductor device A10 has an advantage for improving the bonding reliability of the semiconductor element 3 mounted by flip-chip mounting.

The first conductive portion 6 is disposed adjacent to one of the plurality of first electrodes 34. In the present embodiment, the distance D1 between the first conductive portion 6 and the first electrode 34 adjacent to this is between 100% and 300% of the dimension L3 of the first electrode 34 in the direction orthogonal to the thickness direction z. Such a configuration enhances the accuracy of determining an abnormality exists in the bonding portion of the first electrode 34 when there is no abnormality in the bonding portion of the adjacent first conductive portion 6. This is more preferable for improving the bonding reliability of the semiconductor element 3.

The semiconductor layer 32 (semiconductor element 3) includes the first wiring 325. The first wiring 325 is electrically connected to the first conductive portion 6 and one of the plurality of first electrodes 34. Such a configuration allows the second terminal portion 25 connected to the first conductive portion 6 and the first terminal portion 24 connected to the first electrode 34 to detect changes in the bonding state of the bonding part (bonding layer 61) of the first conductive part 6 or the bonding part (bonding layer 341) of the first electrode 34 as fluctuations in resistance value, by electrically examining the path through the relevant first conductive part 6, the relevant first electrode 34 and the first wiring 325. It is possible to check the bonding state of the bonding portion of the first conductive portion 6 and the first electrode 34, which are electrically connected to the first wiring 325. This improves in the bonding reliability of the semiconductor device A10 with the flip-chip mounted semiconductor element 3.

The ratio of the cross-sectional area (first cross-sectional area) of the first conductive portion 6 in a plane orthogonal to the thickness direction z to the cross-sectional area (second cross-sectional area) of the first electrode 34 in a plane orthogonal to the thickness direction z is between 30% and 95%. The cross-sectional area (first cross-sectional area) of the first conductive portion 6 is smaller than the cross-sectional area (second cross-sectional area) of the first electrode 34. According to the present configuration, changes and abnormalities in the bonding state of the bonding portion of the first conductive portion 6 (bonding layer 61) are significantly evident compared to the bonding portion of the first electrode 34 (bonding layer 341). Such configuration enhances the accuracy of determining whether or not there is an abnormality in the bonding state of the first electrode 34 based on the presence of an abnormality in the bonding state of the first conductive portion 6. This is more desirable in improving the reliability of the junction of the semiconductor element 3. This is more preferable for improving the bonding reliability of the semiconductor element 3.

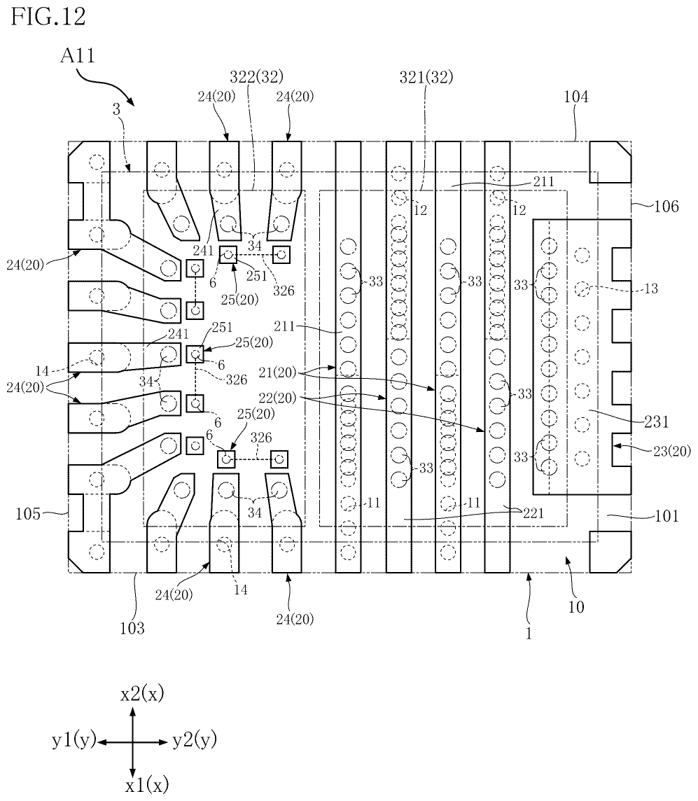

FIGS. 12 to 15 show variations of the semiconductor device of the present disclosure. In these figures, elements identical or similar to the above embodiment are denoted by the same reference signs as those of the above embodiment, and redundant explanations are omitted. Various parts of embodiments may be selectively used in any appropriate combination as long as it is technically compatible.

### First Variation of the First Embodiment

FIG. 12 shows a semiconductor device A11 according to a first variation of the first embodiment. FIG. 12 is a plan view of the semiconductor device A11. In FIG. 12, the semiconductor element 3 and the sealing resin 4 are omitted, for the sake of understanding. In FIG. 12, the omitted semiconductor element 3 is shown as an imaginary line (double-dotted line).

In the present variation of the semiconductor device A11, the semiconductor element 3 includes a second wiring 326 provided in the semiconductor layer 32 instead of the first wiring 325 of the above embodiment. In FIG. 12, the path of the second wiring 326 is indicated by a simplified dotted line. The second wiring 326 is electrically connected to one of the first conductive portion 6 and the other first conductive portion 6. In the illustrated example, the second wiring 326 is electrically connected to the two first conductive portions 6 adjacent to each other. In the example shown in FIG. 12, there are four sets of two adjacent first conductive portions 6 that are electrically connected to the second wiring 326. The second wiring 326 is an example of the “connection checking wiring”.

The semiconductor device A11 comprises the first conductive portion 6. The first conductive portion 6 has a smaller cross-sectional area than the first electrode 34, and is thinner than the first electrode 34. Such a configuration results in the bonding strength between the first conductive portion 6 and the support 1 being lower than the bonding strength between the first electrode 34 and the support 1. It is possible to check the state of the bonding portion of the first conductive portion 6 by electrically examining the relevant bonding of the first conductive portion 6. Since the bonding strength of the first conductive portion 6 is lower than the bonding strength of the first electrode 34 as described above, the fact that there is no abnormality in the bonding portion of the first conductive portion 6 determines that there is no abnormality in the bonding portion of the first electrode 34. Hence, the semiconductor device A11 has an advantage for improving the bonding reliability of the semiconductor element 3 mounted by flip-chip mounting.

The first conductive portion 6 is disposed adjacent to one of the plurality of first electrodes 34. In the present embodiment, the distance D1 between the first conductive portion 6 and the first electrode 34 adjacent to this is between 100% and 300% of the dimension L3 of the first electrode 34 in the direction orthogonal to the thickness direction z. Such a configuration enhances the accuracy of determining an abnormality exists in the bonding portion of the first electrode 34 when there is no abnormality in the bonding portion of the adjacent first conductive portion 6. This is more preferable for improving the bonding reliability of the semiconductor element 3.

The semiconductor layer 32 (semiconductor element 3) includes the second wiring 326. The second wiring 326 is electrically connected to the first conductive portions 6. Such a configuration allows the two second terminal portions 25 connected to the two first conductive portions 6 to detect changes in the bonding state of the first conductive part 6 as fluctuations resistance value, by electrically examining the path through the relevant two first conductive portions 6 and the relevant second wiring 326. Hence, it is possible to check the bonding state of the bonding portion of the first conductive portion 6, which is electrically This improves in the connected to the second wiring 326. bonding reliability of the semiconductor device A11 with the flip-chip mounted semiconductor element 3. In addition, the semiconductor device A11 has the same effects as the semiconductor device A10 of the above embodiment.

### Second Variation of the First Embodiment

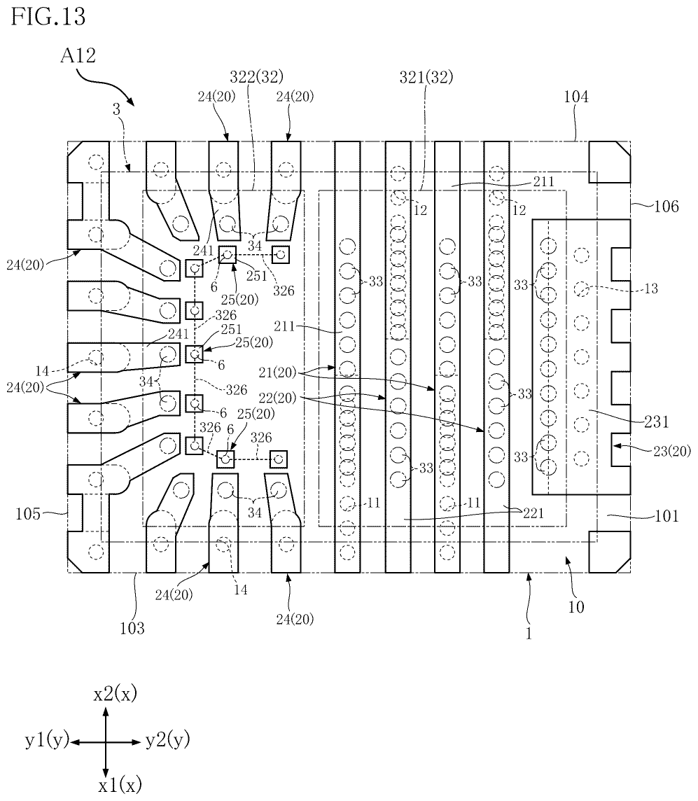

FIG. 13 shows a semiconductor device A12 according to a second variation of the first embodiment. FIG. 13 is a plan view of the semiconductor device A12. In FIG. 13, the semiconductor element 3 and the sealing resin 4 are omitted, for the sake of understanding. In FIG. 13, the omitted semiconductor element 3 is shown as an imaginary line (double-dotted line).

In the present variation of the semiconductor device A12, the semiconductor element 3 includes additional second wirings 326 compared to the semiconductor device A11 of the above first variation. In FIG. 13, the path of the second wirings 326 is indicated by a simplified dotted line. Each second wiring 326 is electrically connected to the two first conductive portions 6 adjacent to each other. The second wirings 326 are provided in all of the pairs of the two first conductive portions 6 adjacent to each other.

The semiconductor device A12 comprises the first conductive portion 6. The first conductive portion 6 has a smaller cross-sectional area than the first electrode 34, and is thinner than the first electrode 34. Such a configuration results in the bonding strength between the first conductive portion 6 and the support 1 being lower than the bonding strength between the first electrode 34 and the support 1. It is possible to check the state of the bonding portion of the first conductive portion 6 by electrically examining the relevant bonding of the first conductive portion 6. Since the bonding strength of the first conductive portion 6 is lower than the bonding strength of the first electrode 34 as described above, the fact that there is no abnormality in the bonding portion of the first conductive portion 6 determines that there is no abnormality in the bonding portion of the first electrode 34. Hence, the semiconductor device A12 has an advantage for improving the bonding reliability of the semiconductor element 3 mounted by flip-chip mounting.

The first conductive portion 6 is disposed adjacent to one of the plurality of first electrodes 34. In the present embodiment, the distance D1 between the first conductive portion 6 and the first electrode 34 adjacent to this is between 100% and 300% of the dimension L3 of the first electrode 34 in the direction orthogonal to the thickness direction z. Such a configuration enhances the accuracy of determining an abnormality exists in the bonding portion of the first electrode 34 when there is no abnormality in the bonding portion of the adjacent first conductive portion 6. This is more preferable for improving the bonding reliability of the semiconductor element 3.

The semiconductor layer 32 (semiconductor element 3) includes the second wiring 326. The second wiring 326 is electrically connected to the first conductive portions 6. Such a configuration allows the two second terminal portions 25 connected to the two first conductive portions 6 to detect changes in the bonding state of the first conductive part 6 as fluctuations in resistance value, by electrically examining the path through the relevant two first conductive portions 6 and the relevant second wiring 326. Hence, it is possible to check the bonding state of the bonding portion of the first conductive portion 6, which is electrically connected to the second wiring 326. This improves in the bonding reliability of the semiconductor device A12 with the flip-chip mounted semiconductor element 3. In the semiconductor device A12, the second wirings 326 are provided in all of the pairs of the two first conductive portions 6 adjacent to each other, so that all of the first conductive portions 6 are electrically connected via the second wirings 326. This allows the paths of the two first conductive portions 6 and second wiring 326 to be electrically measured by using the two relevant second terminal portions 25 selected from the second terminal portions 25 that are connected to all of the first conductive portions 6. Thus, the degree of freedom in checking the bonding states of the first conductive portion 6s is improved. In addition, the semiconductor device A12 has the same effects as the semiconductor device A10 of the above embodiment.

### Third Variation of the First Embodiment

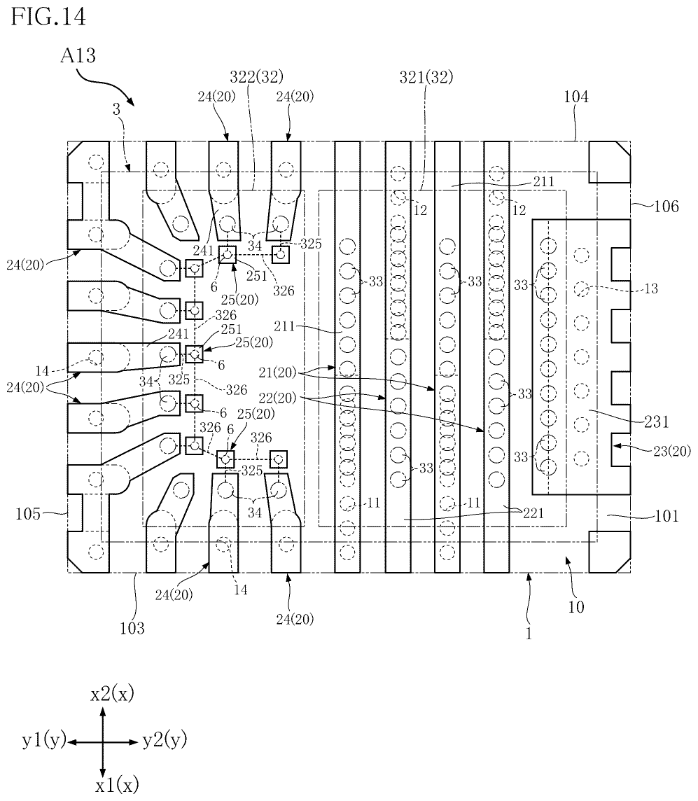

FIG. 14 shows a semiconductor device A13 according to a third variation of the first embodiment. FIG. 14 is a plan view of the semiconductor device A13. In FIG. 14, the semiconductor element 3 and the sealing resin 4 are omitted, for the sake of understanding. In FIG. 14, the omitted semiconductor element 3 is shown as an imaginary line (double-dotted line).

In the semiconductor device A13 of the present variation, the semiconductor element 3 additionally includes the first wirings 325 similar to those of the semiconductor device A10 of the above embodiment compared to the semiconductor device A12 of the above second variation. In the semiconductor device A13 as shown in FIG. 13, the paths of the first wirings 325 and the second wirings 326 are indicated by simplified dotted lines. Each of the first conductive portions 6 is electrically connected via the first wiring 325 to the first electrode 34 adjacent to the relevant first conductive portion 6 and via the second wiring 326 to one or two other first conductive portions 6 adjacent to the relevant first conductive portion 6.

The semiconductor device A13 comprises first conductive portion 6. The first conductive portion 6 has a smaller cross-sectional area than the first electrode 34, and is thinner than the first electrode 34. Such a configuration results in the bonding strength between the first conductive portion 6 and the support 1 being lower than the bonding strength between the first electrode 34 and the support 1. It is possible to check the state of the bonding portion of the first conductive portion 6 by electrically examining the relevant bonding of the first conductive portion 6. Since the bonding strength of the first conductive portion 6 is lower than the bonding strength of the first electrode 34 as described above, the fact that there is no abnormality in the bonding portion of the first conductive portion 6 determines that there is no abnormality in the bonding portion of the first electrode 34. Hence, the semiconductor device A13 has an advantage for improving the bonding reliability of the semiconductor element 3 mounted by flip-chip mounting.

The first conductive portion 6 is disposed adjacent to one of the plurality of first electrodes 34. In the present embodiment, the distance D1 between the first conductive portion 6 and the first electrode 34 adjacent to this is between 100% and 300% of the dimension L3 of the first electrode 34 in the direction orthogonal to the thickness direction z. Such a configuration enhances the accuracy of determining an abnormality exists in the bonding portion of the first electrode 34 when there is no abnormality in the bonding portion of the adjacent first conductive portion 6. This is more preferable for improving the bonding reliability of the semiconductor element 3.

The semiconductor layer 32 (semiconductor element 3) includes the first wiring 325 and the second wiring 326. The first wiring 325 is electrically connected to the first conductive portion 6 and one of the plurality of first electrodes 34. Such a configuration allows the second terminal portion 25 connected to the first conductive portion 6 and the first terminal portion 24 connected to the first electrode 34 to detect changes in the bonding state of the bonding part of the first conductive part 6 or the bonding part of the first electrode 34 as fluctuations in resistance value, by electrically examining the path through the relevant first conductive part 6, the relevant first electrode 34 and the first wiring 325. It is possible to check the bonding state of the bonding portion of the first conductive portion 6 and the first electrode 34, which are electrically connected to the first wiring 325. The second wiring 326 is electrically connected to the first conductive portions 6. Such a configuration allows the two second terminal portions 25 connected to the two first conductive portions 6 to detect changes in the bonding state of the first conductive part 6 as fluctuations in resistance value, by electrically examining the path through the relevant two first conductive portions 6 and the relevant second wiring 326. Hence, it is possible to check the bonding state of the bonding portion of the first conductive portion 6, which is electrically connected to the second wiring 326. This improves in the bonding reliability of the semiconductor device A13 with the flip-chip mounted semiconductor element 3. In the semiconductor device A13, the second wirings 326 are provided in all of the pairs of the two first conductive portions 6 adjacent to each other, so that all of the first conductive portions 6 are electrically connected via the second wirings 326. Further, each of the first conductive portions 6 is electrically connected to the first electrode 34 adjacent to the relevant first conductive portion 6 via the first wiring 325. This allows various wiring paths to be electrically measured by using the two relevant second terminal portions 25 selected from the second terminal portions 25 connected to all of the first conductive portions 6 or by using the two relevant first terminal portions 24 selected from the first terminal portions 24 connected to the first electrodes 34 that are electrically connected to one of the first conductive portions 6 via the relevant first wiring 325. Thus, the degree of freedom in checking the bonding states of the first conductive portions 6 and the first electrodes 34 is improved. In addition, the semiconductor device A13 has the same effects as the semiconductor device A10 of the above embodiment.

### Fourth Variation of the First Embodiment

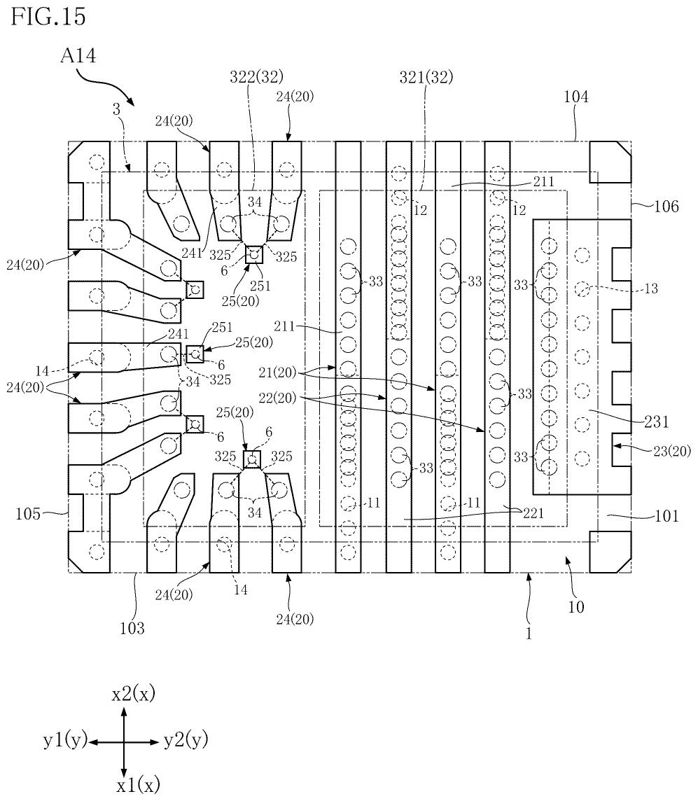

FIG. 15 shows a semiconductor device A14 according to a fourth variation of the first embodiment. FIG. 15 is a plan view of the semiconductor device A14. In FIG. 15, the semiconductor element 3 and the sealing resin 4 are omitted, for the sake of understanding. In FIG. 15, the omitted semiconductor element 3 is shown as an imaginary line (double-dotted line).

In the present variation of the semiconductor device A14, the connection relationships of the first wirings 325 differ from those of the semiconductor device A10 of the above embodiment. Specifically, the quantity of the first conductive portions 6 is smaller than that of the semiconductor device A10. One of the first conductive portions 6 is disposed in correspondence with two mutually adjacent first electrodes 34. The first conductive portions 6 disposed in correspondence with the two first electrodes 34 are electrically connected to the two adjacent first electrodes 34 via the first wiring portion 325.

The semiconductor device A14 comprises the first conductive portion 6. The first conductive portion 6 has a smaller cross-sectional area than the first electrode 34, and is thinner than the first electrode 34. Such a configuration results in the bonding strength between the first conductive portion 6 and the support 1 being lower than the bonding strength between the first electrode 34 and the support 1. It is possible to check the state of the bonding portion of the first conductive portion 6 by electrically examining the relevant bonding of the first conductive portion 6. Since the bonding strength of the first conductive portion 6 is lower than the bonding strength of the first electrode 34 as described above, the fact that there is no abnormality in the bonding portion of the first conductive portion 6 determines that there is no abnormality in the bonding portion of the first electrode 34. Hence, the semiconductor device A14 has an advantage for improving the bonding reliability of the semiconductor element 3 mounted by flip-chip mounting.

The semiconductor layer 32 (semiconductor element 3) includes the first wiring 325. The first wiring 325 is electrically connected to the first conductive portion 6 and one of the plurality of first electrodes 34. Such a configuration allows the second terminal portion 25 connected to the first conductive portion 6 and the first terminal portion 24 connected to the first electrode 34 to detect changes in the bonding state of the bonding part (bonding layer 61) of the first conductive part 6 or the bonding part (bonding layer 341) of the first electrode 34 as fluctuations in resistance value, by electrically examining the path through the relevant first conductive part 6, the relevant first electrode 34 and the first wiring 325. It is possible to check the bonding state of the bonding portion of the first conductive portion 6 and the first electrode 34, which are electrically connected to the first wiring 325. This improves in the bonding reliability of the semiconductor device A10 with the flip-chip mounted semiconductor element 3. In addition, the semiconductor device A14 has the same effects as the semiconductor device A10 of the above embodiment.

The semiconductor devices according to the present disclosure are not limited to the embodiments described above. The specific configuration of each part of a semiconductor device according to the present disclosure may suitably be designed and changed in various manners.

In the above embodiment, the explanation uses the example that the support 1 comprises the substrate 10 and the wiring portion 2, but the present disclosure is not limited thereto. The support in the present disclosure may, for example, be leads made from the same lead frame.

The first conductive portions 6 are disposed in correspondence with the respective first electrodes 34 that are electrically connected to the controlling circuit 322 of the semiconductor layer 32, but is not limited thereto. For example, the first conductive portions 6 may be disposed in correspondence with the electrodes 33 that are electrically connected to the switching circuit 321 of the semiconductor layer 32. In this case, the electrodes 33 correspond to the first electrodes of the present disclosure.

The present disclosure includes the embodiments described in the following clauses.

Clause 1.

A semiconductor device comprising:
a support;
a semiconductor element disposed on one side of the thickness direction of the support and supported by the support; and
one or more first conductive portions,
wherein the semiconductor element includes a circuit portion, an element first face facing another side of the thickness direction, and a plurality of first electrodes provided on the element first face,
the support includes one or more first terminal portions and one or more second terminal portions,
each of the plurality of first electrodes is electrically connected to the circuit portion,
each of the one or more first terminal portions is electrically connected to the circuit portion via at least one of the plurality of first electrodes,
each of the one or more first conductive portions is interposed between each of the one or more second terminal portions and the element first face, and is connected to the second terminal portion and the element first face, and
a first cross-sectional area of the first conductive portion in a plane orthogonal to the thickness direction is smaller than a second cross-sectional area of the first electrode in a plane orthogonal to the thickness direction.

Clause 2.

The semiconductor device according to clause 1, wherein the one or more first conductive portions is disposed adjacent to one of the plurality of first electrodes.

Clause 3.

The semiconductor device according to clause 1 or 2, wherein the one or more first conductive portions comprises a plurality of first conductive portions, and
the semiconductor element includes a connection check wiring electrically connected to one of the first conductive portions and to one of the plurality of first electrodes or another first conductive portion.

Clause 4.

The semiconductor device according to clause 3, wherein the connection check wiring includes a first wiring electrically connected to one of the plurality of first conductive portions and one of the plurality of first electrodes.

Clause 5.

The semiconductor device according to clause 3 or 4, wherein the connection check wiring includes a second wiring electrically connected to one of the plurality of first conductive portions and another first conductive portion.

Clause 6.

The semiconductor device according to any one of clauses 1 to 5, wherein a ratio of the first cross-sectional area to the second cross-sectional area is between 30% and 95%.

Clause 7.

The semiconductor device according to any one of clauses 2 to 5, wherein a distance between the first conductive portion and the first electrode is between 100% and 300% of a dimension of the first electrode in a direction orthogonal to the thickness direction.

Clause 8.

The semiconductor device according to any one of clauses 1 to 7, wherein a dimension of the first conductive portion in the thickness direction is between 250% and 500% of a dimension of the first conductive portion in a direction orthogonal to the thickness direction.

Clause 9.

The semiconductor device according to any one of clauses 1 to 8, further comprising a sealing resin covering the semiconductor element and a part of the support.

Clause 10.

The semiconductor device according to clause 9, wherein the first conductive portion is located inwardly of the sealing resin from the first electrode as viewed: in the thickness direction.

Clause 11.

The semiconductor device according to clause 9 or 10, wherein the support includes a substrate with insulating properties and a wiring portion disposed on a surface of the substrate, and
the wiring portion includes one or more first terminal portions and one or more second terminal portions.

Clause 12.

The semiconductor device according to clause 11, wherein the substrate includes a substrate obverse face facing one side of the thickness direction and covered by the sealing resin, and a substrate reverse face facing another side of the thickness direction,
the first terminal portion includes a first obverse face portion disposed on the substrate obverse face and connected to the first electrode, and
the second terminal portion includes a second obverse face portion disposed on the substrate obverse face and connected to the first conductive portion.

Clause 13.

The semiconductor device according to clause 12, wherein the substrate includes a first through hole and a second through hole that penetrate through the substrate in the thickness direction,
the first terminal portion includes a first reverse face portion disposed on the substrate reverse face, and a first connection portion disposed in the first through hole and connected to the first obverse face portion and the first reverse face portion,
the second terminal portion includes a second reverse face portion disposed on the substrate reverse face, and a second connection portion disposed in the second through hole and connected to the second obverse face portion and the second reverse face portion.

Clause 14.

The semiconductor device according to clause 13, wherein the substrate includes a substrate first side face facing one side in a first direction orthogonal to the thickness direction, a substrate second side face facing another side in the first direction, a substrate third side face facing one side in a second direction orthogonal to the thickness direction and the first direction, and a substrate fourth side face facing another side of the second direction,
the sealing resin includes a resin first side face facing the one side in the first direction and flush with the substrate first side face, a resin second side face facing the another side in the first direction and flush with the substrate second side face, a resin third side face facing the one side of the second direction and flush with the substrate third side face, a resin fourth side face facing the another side of the second direction and flush with the substrate fourth side face.

### REFERENCE NUMERALS

A10 to A14: Semiconductor device
10: Substrate
101: Substrate obverse face
1: Support
102: Substrate reverse face
103: Substrate first side face
104: Substrate second side face
105: Substrate third side face
106: Substrate second side face
11, 12, 13: Through hole
14: First through hole
15: Second through hole
20: Wiring portion
21, 22, 23: Terminal portion
211, 221, 231: Obverse face portion
212,222,232: Reverse face portion
213,223,233: Connection portion
24: First terminal portion
241: First obverse face portion
242: Reverse face portion
243: First connection portion
25: Second terminal portion
251: Second obverse face portion
252: Second reverse face portion
253: Second connection portion
3: Semiconductor element
31: Semiconductor substrate
32: Semiconductor layer
320: Element first face
321: Switching circuit
322: Controlling circuit
325: First wiring
326: Second wiring
33: Electrode
331: Bonding layer
34: First electrode
341: Bonding layer
4: Sealing resin
41: Resin obverse face
42: Resin reverse face
43: Resin first side face
44: Resin second side face
45: Resin third side face
46: Resin fourth side face
6: First conductive portion
61: Bonding layer
D1: Distance
L1, L2, L3: Dimensions
x: First direction
y: Second direction
z: Thickness direction

1. A semiconductor device comprising:
a support;
a semiconductor element disposed on one side of the thickness direction of the support and supported by the support; and
one or more first conductive portions,
wherein the semiconductor element includes a circuit portion, an element first face facing another side of the thickness direction, and a plurality of first electrodes provided on the element first face,
the support includes one or more first terminal portions and one or more second terminal portions,
each of the plurality first of electrodes is electrically connected to the circuit portion,
each of the one or more first terminal portions is electrically connected to the circuit portion via at least one of the plurality of first electrodes,
each of the one or more first conductive portions is interposed between each of the one or more second terminal portions and the element first face, and is connected to the second terminal portion and the element first face, and
a first cross-sectional area of the first conductive portion in a plane orthogonal to the thickness direction is smaller than a second cross-sectional area of the first electrode in a plane orthogonal to the thickness direction.

2. The semiconductor device according to claim 1, wherein the one or more first conductive portions is disposed adjacent to one of the plurality of first electrodes.

3. The semiconductor device according to claim 1, wherein the one or more first conductive portions comprises a plurality of first conductive portions, and
the semiconductor element includes a connection check wiring electrically connected to one of the first conductive portions and to one of the plurality of first electrodes or another first conductive portion.

4. The semiconductor device according to claim 3, wherein the connection check wiring includes a first wiring electrically connected to one of the plurality of first conductive portions and one of the plurality of first electrodes.

5. The semiconductor device according to claim 3, wherein the connection check wiring includes a second wiring electrically connected to one of the plurality of first conductive portions and another first conductive portion.

6. The semiconductor device according to claim 1, wherein a ratio of the first cross-sectional area to the second cross-sectional area is between 30% and 95%.

7. The semiconductor device according to claim 2, wherein a distance between the first conductive portion and the first electrode is between 100% and 300% of a dimension of the first electrode in a direction orthogonal to the thickness direction.

8. The semiconductor device according to claim 1, wherein a dimension of the first conductive portion in the thickness direction is between 250% and 500% of a dimension of the first conductive portion in a direction orthogonal to the thickness direction.

9. The semiconductor device according to claim 1, further comprising a sealing resin covering the semiconductor element and a part of the support.

10. The semiconductor device according to claim 9, wherein the first conductive portion is located inwardly of the sealing resin from the first electrode as viewed in the thickness direction.

11. The semiconductor device according to claim 9, wherein the support includes a substrate with insulating properties and a wiring portion disposed on a surface of the substrate, and
the wiring portion includes one or more first terminal portions and one or more second terminal portions.

12. The semiconductor device according to claim 11, wherein the substrate includes a substrate obverse face facing one side of the thickness direction and covered by the sealing resin, and a substrate reverse face facing another side of the thickness direction,
the first terminal portion includes a first obverse face portion disposed on the substrate obverse face and connected to the first electrode, and
the second terminal portion includes a second obverse face portion disposed on the substrate obverse face and connected to the first conductive portion.

13. The semiconductor device according to claim 12, wherein the substrate includes a first through hole and a second through hole that penetrate through the substrate in the thickness direction,
the first terminal portion includes a first reverse face portion disposed on the substrate reverse face, and a first connection portion disposed in the first through hole and connected to the first obverse face portion and the first reverse face portion,
the second terminal portion includes a second reverse face portion disposed on the substrate reverse face, and a second connection portion disposed in the second through hole and connected to the second obverse face portion and the second reverse face portion.

14. The semiconductor device according to claim 13, wherein the substrate includes a substrate first side face facing one side in a first direction orthogonal to the thickness direction, a substrate second side face facing another side in the first direction, a substrate third side face facing one side in a second direction orthogonal to the thickness direction and the first direction, and a substrate fourth side face facing another side of the second direction,
the sealing resin includes a resin first side face facing the one side in the first direction and flush with the substrate first side face, a resin second side face facing the another side in the first direction and flush with the substrate second side face, a resin third side face facing the one side of the second direction and flush with the substrate third side face, a resin fourth side face facing the another side of the second direction and flush with the substrate fourth side face.
